(19) United States
(12) Patent Application Publication
(10) Pub. No.: US 2007/0118857 A1
(43) Pub. Date: May 24, 2007

(54) System and method of recording video content

(75) Inventors: Zesen Chen, Pleasanton, CA (US); Peter Chou, San Ramon, CA (US)

Correspondence Address: LARSON NEWMAN ABEL POLANSKY & WHITE, LLP, 5914 WEST COURTYARD DRIVE, SUITE 200, AUSTIN, TX, 78730, US

(73) Assignee: SBC Knowledge Ventures, L.P., Reno, NV (US)

(21) Appl. No.: 11/283,507

(22) Filed: Nov. 18, 2005

(51) Int. Cl. H04N 5/445; G06F 13/00; G06F 3/00; H03G 3/20; G06F 17/00; H04N 7/173; H04R 3/00; G06F 9/00

(52) U.S. Cl. 725/61; 725/100; 725/131; 715/728; 381/110; 725/122; 725/58

(57) ABSTRACT

A system and method of recording video content is disclosed. In a particular embodiment, the method includes receiving a call at a set-top box device, where the call is routed using an identifier associated with the set-top box device. The method also includes receiving a voice command at the set-top box device, where the voice command identifies selected video content to be recorded. Additionally, the method includes receiving the selected video content via an external access network coupled to the set-top box device and includes recording the selected video content at the set-top box device.

### FIELD OF THE DISCLOSURE

The present disclosure is generally related to recording video content.

### BACKGROUND

Television and films provide sources of information and entertainment to many viewers. Often, viewers cannot watch television programs or movies because they are engaged in other activities. Thus, many viewers record television and movie content. Recording video content enables viewers to miss a broadcast of a movie or television program, yet watch the movie or program at another time. Additionally, recording video content allows viewers to watch a movie or program multiple times.

While recording video content can be convenient, scheduling such recording often requires proximity to recording equipment, such as a video cassette recorder or digital video recorder. If a user forgets to schedule a device to record a program or movie and leaves the location of the video recording device, they may be forced to wait for a rebroadcast of the content that they missed. Accordingly, there is a need for an improved system and method of recording video content.

### BRIEF DESCRIPTION OF THE DRAWINGS

FIG. 1 is a block diagram illustrating an embodiment of an Internet Protocol Television (IPTV) system;

FIG. 2 is a block diagram illustrating an embodiment of a system to record video content;

FIG. 3 is a flow diagram illustrating an embodiment of a method of recording video content;

FIG. 4 is a flow diagram illustrating a second embodiment of a method of recording video content;

FIG. 5 is a flow diagram illustrating a third embodiment of a method of recording video content; and

FIG. 6 is a diagram of an embodiment of a general computer system.

### DETAILED DESCRIPTION OF THE DRAWINGS

A system and method of recording video content is disclosed. In a particular embodiment, the method includes receiving a call at a set-top box device, where the call is routed using an identifier associated with the set-top box device. The method also includes receiving a voice command at the set-top box device, where the voice command identifies selected video content to be recorded. Additionally, the method includes receiving the selected video content via an external access network coupled to the set-top box device and includes recording the selected video content at the set-top box device.

In another embodiment, the method includes routing a call over a telephone network to a remote set-top box device using an identifier associated with the set-top box device and communicating a voice command to the remote set-top box device during the call. The voice command identifies selected video content to be recorded at the remote set-top box device.

In another embodiment, the method of recording video content includes receiving a call at a server within an Internet Protocol Television (IPTV) system, where the call is routed using an identifier associated with the server. The method also includes associating the call with a set-top box device. Further, the method includes receiving a voice command at the server, where the voice command identifies selected video content to be recorded. Additionally, the method includes issuing a programming command to a device via the IPTV system to record the selected video content.

In another embodiment, a set-top box device is disclosed and includes a telephone network interface configured to receive a call routed using an identifier associated with the set-top box device. The set-top box device also includes a voice command logic module configured to receive a voice command via the telephone network interface, where the voice command identifies selected video content to be recorded. Additionally, the set-top box device includes a video content storage module responsive to the voice command logic module to record the selected video content.

In another embodiment, a computer program embedded in a computer-readable media is disclosed and includes instructions to process a received voice command communicated during an incoming call to a set-top box device, where the call is routed using an identifier associated with the set-top box device. The voice command identifies selected video content to be recorded. The computer program also includes instructions to schedule recording of the selected video content at a video content storage module of the set-top box device.

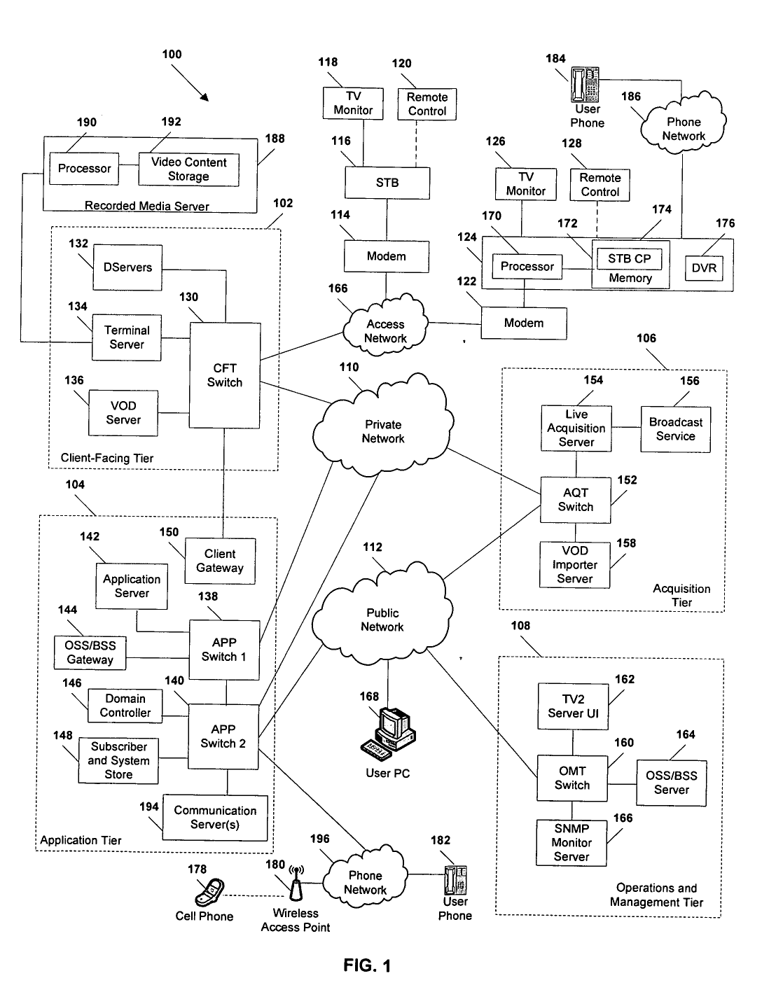

Referring to FIG. 1, an illustrative embodiment of an Internet Protocol Television (IPTV) system that may be used to record video content is illustrated and is generally designated 100. As shown, the system 100 can include a client facing tier 102, an application tier 104, an acquisition tier 106, and an operations and management tier 108. Each tier 102, 104, 106, 108 is coupled to a private network 110; to a public network 112, such as the Internet; or to both the private network 110 and the public network 112. For example, the client-facing tier 102 can be coupled to the private network 110. Further, the application tier 104 can be coupled to the private network 110 and to the public network 112. The acquisition tier 106 can also be coupled to the private network 110 and to the public network 112. Additionally, the operations and management tier 108 can be coupled to the public network 112.

As illustrated in FIG. 1, the various tiers 102, 104, 106, 108 communicate with each other via the private network 110 and the public network 112. For instance, the client-facing tier 102 can communicate with the application tier 104 and the acquisition tier 106 via the private network 110. The application tier 104 can also communicate with the acquisition tier 106 via the private network 110. Further, the application tier 104 can communicate with the acquisition tier 106 and the operations and management tier 108 via the public network 112. Moreover, the acquisition tier 106 can communicate with the operations and management tier 108 via the public network 112. In a particular embodiment, elements of the application tier 104, including, but not limited to, a client gateway 150, can communicate directly with the client-facing tier 102.

As illustrated in FIG. 1, the client-facing tier 102 can communicate with user equipment via a private access network 166, such as an Internet Protocol Television (IPTV) access network. In an illustrative embodiment, modems, such as a first modem 114 and a second modem 122 can be coupled to the private access network 166. The client-facing tier 102 can communicate with a first representative set-top box device 116 via the first modem 114 and with a second representative set-top box device 124 via the second modem 122. The client-facing tier 102 can communicate with a large number of set-top boxes, such as the representative set-top boxes 116, 124, over a wide geographic area, such as a regional area, a metropolitan area, a viewing area, or any other suitable geographic area that can be supported by networking the client-facing tier 102 to numerous set-top box devices.

In a particular embodiment, the client-facing tier 102 can be coupled to the modems 114, 122 via fiber optic cables. Alternatively, the modems 114 and 122 can be digital subscriber line (DSL) modems that are coupled to one or more network nodes via twisted pairs, and the client-facing tier 102 can be coupled to the network nodes via fiber-optic cables. Each set-top box device 116, 124 can process data received via the private access network 166, via an IPTV software platform, such as Microsoft® TV IPTV Edition.

Additionally, the first set-top box device 116 can be coupled to a first external display device, such as a first television monitor 118, and the second set-top box device 124 can be coupled to a second external display device, such as a second television monitor 126. Moreover, the first set-top box device 116 can communicate with a first remote control 120, and the second set-top box device can communicate with a second remote control 128.

In an exemplary, non-limiting embodiment, each set-top box device 116, 124 can receive video content, which may include video and audio portions, from the client-facing tier 102 via the private access network 166. The set-top boxes 116, 124 can transmit the video content to an external display device, such as the television monitors 118, 126. Further, the set-top box devices 116, 124 can each include a STB processor, such as STB processor 170, and a STB memory device, such as STB memory 172, which is accessible to the STB processor 170. In one embodiment, a computer program, such as the STB computer program 174, can be embedded within the STB memory device 172. Each set-top box device 116, 124 can also include a video content storage module, such as a digital video recorder (DVR) 176. In a particular embodiment, the set-top box devices 116, 124 can communicate commands received from the remote control devices 120, 128 to the client-facing tier 102 via the private access network 166.

In an illustrative embodiment, the client-facing tier 102 can include a client-facing tier (CFT) switch 130 that manages communication between the client-facing tier 102 and the private access network 166 and between the client-facing tier 102 and the private network 110. As shown, the CFT switch 130 is coupled to one or more data servers 132 that store data transmitted in response to user requests, such as video-on-demand material, or that encode video content for transmission to the set-top box devices 116, 124. The CFT switch 130 can also be coupled to a terminal server 134 that provides terminal devices, such as a recorded media server 188 and other devices, with a connection point to the private network 110. In a particular embodiment, the CFT switch 130 can also be coupled to a video-on-demand (VOD) server 136 that stores or provides VOD content imported by the IPTV system 100.

As illustrated in FIG. 1, the application tier 104 can communicate with both the private network 110 and the public network 112. The application tier 104 can include a first application tier (APP) switch 138 and a second APP switch 140. In a particular embodiment, the first APP switch 138 can be coupled to the second APP switch 140. The first APP switch 138 can be coupled to an application server 142 and to an OSS/BSS gateway 144. The application server 142 provides applications to the set-top box devices 116, 124 via the private access network 166, so the set-top box devices 116, 124 can provide functions, such as display, messaging, processing of IPTV data and VOD material, etc. In a particular embodiment, the OSS/BSS gateway 144 includes operation systems and support (OSS) data, as well as billing systems and support (BSS) data. In one embodiment, the OSS/BSS gateway can provide or restrict access to an OSS/BSS server 164 that stores operations and billing systems data.

Further, the second APP switch 140 can be coupled to a domain controller 146 that provides web access, for example, to users via the public network 112. For example, the domain controller 146 can provide remote web access to IPTV account information via the public network 112, which users can access using their personal computers 168. The second APP switch 140 can be coupled to a subscriber and system store 148 that includes account information, such as account information that is associated with users who access the system 100 via the private network 110 or the public network 112. In a particular embodiment, the application tier 104 can also include a client gateway 150 that communicates data directly with the client-facing tier 102. In this embodiment, the client gateway 150 can be coupled directly to the CFT switch 130. The client gateway 150 can provide user access to the private network 110 and the tiers coupled thereto.

In a particular embodiment, the set-top box devices 116, 124 can access the IPTV system 100 via the private access network 166, using information received from the client gateway 150. In this embodiment, the private access network 166 can provide security for the private network 110. User devices can access the client gateway 150 via the private access network 166, and the client gateway 150 can allow such devices to access the private network 110 once the devices are authenticated or verified. Similarly, the client gateway 150 can prevent unauthorized devices, such as hacker computers or stolen set-top box devices from accessing the private network 110, by denying access to these devices beyond the private access network 166.

For example, when a set-top box device 116 accesses the system 100 via the private access network 166, the client gateway 150 can verify subscriber information by communicating with the subscriber and system store 148 via the private network 110, the first APP switch 138, and the second APP switch 140. Further, the client gateway 150 can verify billing information and status by communicating with the OSS/BSS gateway 144 via the private network 110 and the first APP switch 138. In one embodiment, the OSS/BSS gateway 144 can transmit a query across the first APP switch 138, to the second APP switch 140, and the second APP switch 140 can communicate the query across the public network 112 to the OSS/BSS server 164. After the client gateway 150 confirms subscriber and/or billing information, the client gateway 150 can allow the set-top box device 116 access to IPTV content and VOD content. If the client gateway 150 cannot verify subscriber information for the set-top box device 116, e.g., because it is connected to an unauthorized twisted pair, the client gateway 150 can block transmissions to and from the set-top box device 116 beyond the private access network 166.

In an illustrative embodiment, the second APP switch 140 can be coupled to one or more communication servers 194 that communicate with a phone network 196, such as a public-switched telephone network (PSTN) or a plain old telephone service (POTS) network, via the second APP switch 140. The communication server(s) 194 can receive incoming calls from a caller phone 182, or from a cellular phone 178 via a wireless access point 180. Calls can be routed using identifiers, such as telephone numbers associated with the communication servers 194. For instance, calls issued to a phone associated with the communication server(s) 194 can be received at a call center and routed to the communication server(s) 194.

As indicated in FIG. 1, the acquisition tier 106 includes an acquisition tier (AQT) switch 152 that communicates with the private network 110. The AQT switch 152 can also communicate with the operations and management tier 108 via the public network 112. In a particular embodiment, the AQT switch 152 can be coupled to a live acquisition server 154 that receives television or movie content, for example, from a broadcast service 156. In a particular embodiment during operation of the IPTV system, the live acquisition server 154 can acquire television or movie content. The live acquisition server 154 can transmit the television or movie content to the AQT switch 152, and the AQT switch 152 can transmit the television or movie content to the CFT switch 130 via the private network 110.

Further, the television content can be encoded at the data servers 132, and the CFT switch 130 can communicate the television or movie content to the modems 114, 122 via the private access network 166. The set-top box devices 116, 124 can receive the television or movie content via the modems 114, 122, and transmit the television or movie content to the television monitors 118, 126. In an illustrative embodiment, video or audio portions of the television or movie content can be streamed to the set-top box devices 116, 124.

Further, the AQT switch can be coupled to a video-on-demand importer server 158 that stores television or movie content received at the acquisition tier 106 and communicates the stored content to the VOD server 136 at the client-facing tier 102 via the private network 110. Additionally, at the acquisition tier 106, the video-on-demand (VOD) importer server 158 can receive content from one or more VOD sources outside the IPTV system 100, such as movie studios and programmers of non-live content. The VOD importer server 158 can transmit the VOD content to the AQT switch 152, and the AQT switch 152, in turn, can communicate the material to the CFT switch 130 via the private network 110. The VOD content can be stored at one or more servers, such as the VOD server 136.

When user issue requests for VOD content via the set-top box devices 116, 124, the requests can be transmitted over the private access network 166 to the VOD server 136, via the CFT switch 130. Upon receiving such requests, the VOD server 136 can retrieve the requested VOD content and transmit the content to the set-top box devices 116,124 across the private access network 166, via the CFT switch 130. The set-top box devices 116, 124 can transmit the VOD content to the television monitors 118, 126. In an illustrative embodiment, video or audio portions of VOD content can be streamed to the set-top box devices 116, 124.

FIG. 1 further illustrates that the operations and management tier 108 can include an operations and management tier (OMT) switch 160 that conducts communication between the operations and management tier 108 and the public network 112. In the embodiment illustrated by FIG. 1, the OMT switch 160 is coupled to a TV2 server 162. Additionally, the OMT switch 160 can be coupled to an OSS/BSS server 164 and to a simple network management protocol (SNMP) monitor 170 that monitors network devices within or coupled to the IPTV system 100. In a particular embodiment, the OMT switch 160 can communicate with the AQT switch 152 via the public network 112.

In an illustrative embodiment, the live acquisition server 154 can transmit the television or movie content to the AQT switch 152, and the AQT switch 152, in turn, can transmit the television or movie content to the OMT switch 160 via the public network 112. In this embodiment, the OMT switch 160 can transmit the television or movie content to the TV2 server 162 for display to users accessing the user interface at the TV2 server 162. For example, a user can access the TV2 server 162 using a personal computer (PC) 168 coupled to the public network 112.

As illustrated in FIG. 1, the system 100 can include a recorded media server 188 coupled to the terminal server 134. The recorded media server 188 can include a processor 190 and a video content storage module 192 that is accessible to the processor 190. The video content storage module 192 can record and store video content that a user has requested to be recorded. In one embodiment, the video content storage module 192 can include one or more logically partitioned or virtual DVRs.

In a particular embodiment, the communication server(s) 194 can receive an incoming call from a user phone 182 or a user cellular phone 178 via the telephone network 196. The call can be routed using an identifier associated with the communication server(s) 194, such as a telephone number of a call center coupled to the communication server(s) 194. During the call, one or more voice commands that indicate video content that the user wants to be recorded can be communicated to the communication server(s) 194 via the telephone network 196. The voice command(s) can also indicate a time and other data necessary to schedule recording of the video content.

The communication server(s) 194 can associate the call with a user's set-top box device 116, 124, for example, by querying the subscriber and system store 148 for an identifier of a set-top box device 116, 124 associated with caller ID information, a voice print match, or other personal identifier received during the call. In a particular embodiment, the communication server(s) 194, or a device communicating with the communication server(s) 194, can include logic or instructions to issue programming or scheduling commands to a DVR within the user's set-top box device, such as the DVR 176 at set-top box 124, to record the selected video content at the scheduled time. The set-top box 124 can receive the selected video content from the client-facing tier 102 via the private access network 166 and record the selected video content using the DVR 176.

In another particular embodiment, the communication server(s) 194, or a device communicating with the communication server(s) 194, can include logic or instructions to issue programming or scheduling commands to the recorded media server 188 via the private network 110, to record selected video content corresponding to the voice commands. The recorded media server 188 can receive the selected video content from the acquisition tier 106 via the private network 110 and record the selected video content at the scheduled time. In a particular embodiment, the recorded media server 188 can transmit the selected video content to the user's set-top box device 116, 124, via the private access network 166, when the user issues a request from the set-top box device 116, 124, to download the recorded video content.

In a particular embodiment, the video content storage module 192 within the recorded media server 188 can include one or more partitioned or virtual digital video recorders (DVRs). For example, a call can be associated with a virtual DVR within the video content storage module 192, using caller ID information, a voice print match, or a personal identifier received during the call. Video content corresponding to voice commands received during the call can be recorded and stored via the user's virtual DVR. In one embodiment, the user can enter a personal identifier via the set-top box device 116, 124 that allows the user to download recorded video content from his or her virtual DVR.

In another embodiment, an incoming call can be received at a set-top box device, such as the set-top box device 124, from a user phone 184, via a telephone network 186, such as a POTS network. The call can be routed to the set-top box device 124 using an identifier associated with the set-top box device 124. In an illustrative embodiment, the set-top box device 124 can receive calls issued to a telephone number associated with the set-top box device 124. During the call, one or more voice commands can be communicated to the set-top box device 124 via the telephone network 186. The voice command(s) can indicate video content that the user wants to be recorded at the set-top box device 124. The set-top box device 124 can include logic or instructions to issue programming or scheduling commands to record video content corresponding to the voice commands to a DVR 176 within the set-top box device 124. The DVR 176 can receive the selected video content via the private access network 166 and record the selected video content at the scheduled time. In an example embodiment, if the video content includes VOD content, the set-top box device 124 can include logic to request or retrieve the VOD content from the IPTV system 100 via the private access network 166.

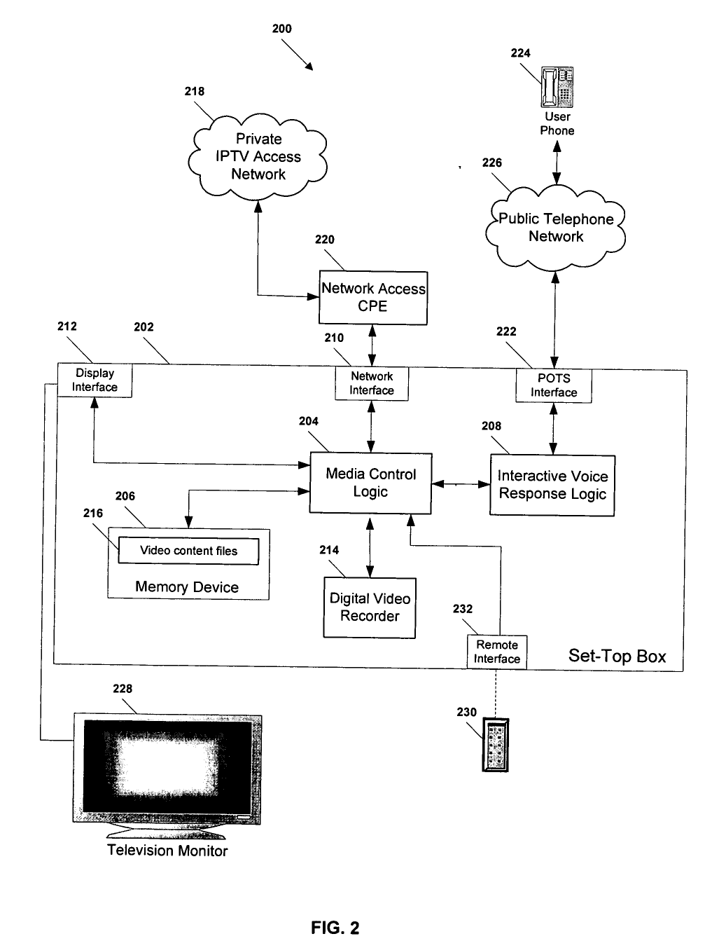

Referring to FIG. 2, an embodiment of a system to record video content is illustrated and designated generally at 200. The system includes a set-top box 202 that contains a media control logic module 204. A memory device 206 is accessible to the media control logic module 204. Additionally, the media control logic module 204 is coupled to a network interface 210.

In a particular embodiment, the media control logic module 204 can be coupled to a voice command logic module, such as an interactive voice response logic module 208. In an alternative embodiment, the media control logic module 204 and the interactive voice response logic module 208 can be included within a single device, such as a processor.

Further, the media control logic module 204 can be coupled to a display interface 212, such as a television interface, through which the set-top box device 202 can communicate video content to an external display device, such as a television monitor 228. The media control logic module 204 is also coupled to a video content storage module, such as a digital video recorder (DVR) 214 that records and stores video content received at the set-top box device 202. In addition, the media control logic module 204 can communicate with a remote control device 230, via a remote control interface 232.

The media control logic module 204 can communicate with an external access network, such as a private Internet Protocol Television (IPTV) access network 218, via the network interface 210. In an illustrative embodiment, network access customer premises equipment 220 can facilitate communication between the network interface 210 and the private IPTV access network 218. The network access CPE 220 can include a router, local area network device, a modem, such as a digital subscriber line (DSL) modem, any other suitable device for facilitating communication between the network interface 210 of the set-top box device 202 and the IPTV access network 218, or any combination thereof.

In a particular embodiment, the memory device 206 can store video content files 216. In an illustrative embodiment, the video content files 216 can include video content that is stored at a network device, such as a recorded media server or network DVR, within an IPTV system that is accessible to the set-top box device 202 via the private IPTV access network 218. Such video content can be downloaded to the set-top box device 202 as one or more video content files 216 and can be stored within the memory device 206. In another embodiment, video content recorded at the DVR 214 within the set-top box device 202 can be stored as video content files 216 within the memory device 206. For example, video content stored at the DVR 214 for longer than a certain period of time, or video content that has been viewed but not deleted from the DVR 214, can be stored at the memory device 206.

In one embodiment, the media control logic module 204 is configured to receive voice commands from a telephone interface, such as a POTS interface 222, via the interactive voice response logic module 208. Additionally, the media control logic module 204 can include logic or instructions to issue programming commands to the DVR 214 to schedule recording of video content corresponding to the voice command(s). Further, the media control logic module 204 can include logic or instructions to receive the selected video content identified by the voice command(s) from a server accessible via the private IPTV access network 218.

In a particular embodiment, an incoming call from the user phone 224 can terminate at the POTS interface 222 of the set-top box device 202. The call can be routed over the public telephone network 226, using a phone number or other identifier associated with the set-top box device 202. The interactive voice response module 208 can include logic or instructions to answer the call. During the call, the interactive voice response module 208 can receive one or more voice commands from the user phone 224 that identify video content to be recorded, as well as a date, time, television station or video content channel, or other data corresponding to the selected video content. The selected video content can include movie content, video-on-demand content, broadcast television content, or a combination thereof.

In an illustrative embodiment, the interactive voice response module 208 can include logic or instructions to provide a menu having at least one level, which prompts users to select video content to be recorded, as well as data corresponding to the selected video content, via voice commands, key inputs, or both. Various data for which a user can be prompted by the interactive voice response module 208 can include, for example, a video-on-demand program title, a movie program title, a movie channel, a television station call letter, a television station call number, a television channel number, a television program title, a user-defined television station identifier, a user-defined movie channel identifier, a movie time, a television program time, a movie date, a television program date, or a combination thereof. In one embodiment, the interactive voice response module 208 can prompt the caller for video content and related data, by providing a multi-level menu to the caller.

For instance, when the interactive voice response module 208 receives an incoming call, it can provide a main menu level, such as ‘say 1 for record options; or say 2 for management options.’ In another example, the user can say ‘record options,’ and the interactive voice response module 208 can output ‘say or press 1 for television programs; say or press 2 for movies; say or press 3 for video-on-demand,’ and similar verbal statements. In one embodiment, if the user designates television programs by speaking ‘one,’ the interactive voice response module 208 can output a next menu level, such as, ‘say 1 for programs airing today; say 2 for programs airing tomorrow,’ and similar verbal statements. In another embodiment, if the user designates television programs airing tomorrow, by speaking ‘two,’ the interactive voice response module 208 can output a next menu level, such as ‘say the channel number for the program you wish to record, or enter it using your keypad,’ or a similar verbal statement.

In a particular embodiment, the interactive voice response module 208 can be implemented using hardware logic adapted to receive voice or other input commands from the user phone 224 via the POTS interface 222 and transmit corresponding signals or commands to the media control logic module 204. Alternatively, the interactive voice response module 208 can include a device that contains computer-readable instructions to process the voice or other input commands and transmit corresponding signals to the media control logic module 204. In another example, the interactive voice response module 208 can include a combination of hardware and computer-readable instructions suited to receive voice or other input commands during an incoming call from a user phone 224 via the POTS interface 222 and to transmit corresponding signals or commands to the media control logic module 204.

The media control logic module 204 can include logic or instructions to receive and process the commands or signals that are transmitted by the interactive voice response module 208. In a particular embodiment, the media control logic module 204 can include logic adapted to carry out a variety of functions, based at least partially on the voice or other input command(s). Alternatively, the media control logic module 204 can include a device that contains computer-readable instructions to perform functions, based at least partially on the voice or other input command(s). In another embodiment, the media control logic module 204 can include a combination of hardware and computer-readable instructions suited to perform functions, based at least partially on the voice or other input command(s).

For example, the media control logic module 204 can include logic or instructions to schedule the DVR 214, based at least partially on the voice or other input command(s), to record selected video content at a time, date and channel associated with the selected video content. The media control logic module 204 can include logic or instructions to schedule the DVR 214 to record the selected video content, by issuing one or more programming commands to the DVR 214.

Additionally, the media control logic module 204 can include logic or instructions to receive selected video content from the private IPTV access network 218 via the set-top box network interface 210. The media control logic module 204 can include logic or instructions to transmit the selected video content to the DVR 214, where the selected video content is recorded. In an illustrative embodiment, if the selected video content is VOD content, the media control logic module 204 can include logic or instructions to retrieve the selected video content from a VOD server via the private IPTV access network 218 and to transmit the selected video content to the DVR 214 to be recorded. In this embodiment, the media control logic module 204 can include logic or instructions to generate one or more requests for the selected video content and transmit the request(s) to the private IPTV access network 218, via the network interface 210.

In a particular embodiment, the media control logic module 204 can include logic or instructions to execute voice or other input commands received by the interactive voice response module 208, which relate to management of the DVR 214 or the video content files 216. For example, the interactive voice response module 208 can include logic or instructions to receive voice or other input commands to restrict video content that can be recorded at the set-top box device 202; to delete recorded video content from the DVR 214 or the video content files 216; to schedule playback of recorded video content; or to restrict access to recorded video content. Voice or other input commands corresponding to such management functions can be received during a call by the interactive voice response module 208, for example, via a menu feature having at least one menu level. In one embodiment, the interactive voice response module 208 can include logic or instructions to provide a multi-level menu to prompt a user for management commands.

The interactive voice response module 208 can include logic or instructions to transmit commands or signals corresponding to management commands that it receives from the user phone 224, to the media control logic module 204. The media control logic module 204 can include logic or instructions to receive and process the commands or signals to carry out functions based at least partially on the voice or other input commands received from the user phone 224 at the interactive voice response module 208. For example, the media control logic module 204 can include logic or instructions to issue commands to the DVR 214 or to the memory device 206 to delete a recorded movie or television program or a video content file 216. In another example, the media control logic module 204 can include logic or instructions to block transmission of restricted video content received from the network interface 210 to the DVR 214, or from the DVR 214 to the display interface 212, unless a credential is received at the set-top box device 202, for example, from a remote control device 230 or via the interactive voice response module 208.

In an illustrative embodiment, the media control logic module 204 can include logic or instructions to output recorded video content from the DVR 214 or the video content files 216 to the television monitor 228. The media control logic module 204 can include logic or instructions to receive a command from the remote control 230, for example, to playback recorded video content. The media control logic module 204 can include logic or instructions to retrieve the video content from the DVR 214 or the video content files 216 and to transmit a signal corresponding to the video content to the television monitor 228. In one embodiment, the media control logic module 204 can generate a list or menu of recorded video content and transmit the list or menu to the television monitor 228 via the display interface 212. The user can select recorded video content from the list or menu, for example, using arrow keys on the remote control device 230. The media control logic module 204 can retrieve, transmit, or retrieve and transmit, selected video content to the television monitor 228.

In a particular embodiment, the media control logic module 204 can include logic or instructions to receive a command to download recorded video content from a server within an IPTV system, via the private IPTV access network 218. For example, a user can issue a command requesting video content recorded at a network DVR, using the remote control device 230. The media control logic module 204 can receive the command via the remote interface 232. In one embodiment, the media control logic module 204 can retrieve a list of recorded video content at a network DVR or virtual network DVR associated with the set-top box device 202 and transmit the list to the television monitor 228 via the display interface 212. In this embodiment, the user can select recorded video content from the list, for example, by using arrow keys on the remote control device 230. The media control logic module 204 can retrieve selected video content via the private IPTV access network 218 and the selected video content can be stored locally at the DVR 214 or within the memory device 206.

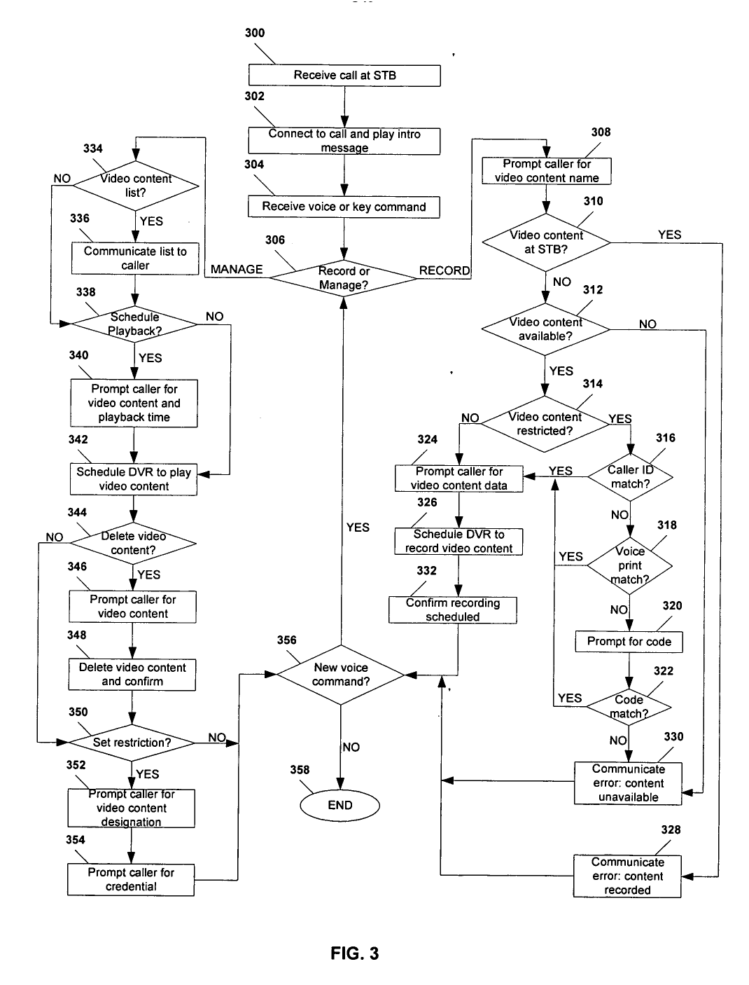

Referring to FIG. 3, a particular illustrative embodiment of a method of recording video content is disclosed. At block 300, an incoming call is received at a set-top box device. The call can be routed over a public telephone network, such as a plain old telephone service (POTS) network, using an identifier associated with the set-top box device. In one embodiment, the call can be routed using a telephone number associated with the set-top box device. Alternatively, a Voice over Internet Protocol (VoIP) call could be placed. Continuing to block 302, the set-top box device receives the call. In a particular embodiment, an interactive voice response logic module (IVR) within the set-top box device can answer the call and communicate an introductory message that informs the caller that the set-top box device has answered the call.

Proceeding to block 304, a voice command can be received during the call. In an illustrative embodiment, the IVR can present the caller with a main menu that includes selectable options to record or manage video content at the set-top box device. The caller can speak a voice command corresponding to one of the menu selections, such as ‘record’ or ‘manage.’ In another embodiment, the caller can speak, for example, ‘one,’ corresponding to ‘record’ or ‘two’ corresponding to ‘manage.’ Moving to decision step 306, the IVR can determine whether a selection to record video content or manage recorded content has been received from the caller. If a selection to record video content is received, the method continues to block 308. On the other hand, if a selection to manage recorded content has been received, the method moves to decision step 334.

In a particular embodiment, at block 308, the caller can be prompted for video content that the caller wishes to be recorded at the set-top box device. The video content can include movie content, video-on-demand content, broadcast television content, or a combination thereof. For example, if a caller chooses a selection to record video content from a menu, the menu can move to a next menu level that prompts the caller for a name of a video program, television program, or movie that the caller wishes to record. The caller can input the video content name, for instance, by speaking the name of the video content, or by issuing a voice command in response to a menu of selectable video content. Alternatively, the caller can input one or more letters included in the video content name using telephone keys, such as keys that generate dual tone multi frequency (DTMF) signals, and the caller could then select from video content choices having those letters.

Moving to decision step 310, it is determined whether the video content selected by the caller is stored at the set-top box device. In one embodiment, the IVR, or other hardware or software communicating with the IVR, can determine whether the selected video content is stored at a digital video recorder (DVR) or memory device within the set-top box device. If the video content is stored at the set-top box device, then the method proceeds to block 328, and a message indicating that the selected video content has already been recorded can be communicated to the caller. The method then continues to decision step 356. Conversely, if the video content is not stored at the set-top box device, the method proceeds to decision step 312.

At decision step 312, it is determined whether the selected video content is available for recording. In an illustrative embodiment, the IVR, or other hardware or software communicating with the IVR, can query one or more servers within an IPTV system for availability of the video content selected by the caller. For instance, if the selected video content is a movie that is not being shown on broadcast television, on movie channels, or from video-on-demand or pay-per-view providers, the IVR can receive an indication from the IPTV system that the selected video content is unavailable to be recorded. If the selected video content is not available to be recorded, the method can proceed to block 330, and an error message indicating that the selected video content is unavailable can be communicated by the IVR to the caller. The method then continues to decision step 356. On the other hand, if the selected video content is available, the method moves to decision step 314.

In a particular embodiment, at decision step 314, it can be determined whether the selected video content is restricted from being recorded at the set-top box device. The set-top box can store one or more designations of restricted video content set by a user of the set-top box device, such as a parent or set-top box owner or lessee. Such designations can be stored according to video content names, video content audience ratings, television or movie channels, pay-per-view channels, or video-on-demand channels. Additionally, the user can also designate credentials that must be supplied before restricted video content can be recorded at the set-top box device. These credentials may include caller identification information, one or more voice prints associated with the caller, a personal identification number (PIN), a password or passcode, any other suitable credential, or any combination thereof. If the selected video content is restricted, the method moves to decision step 316; whereas, if the selected video content is not restricted, the method continues to block 324 and continues.

In an illustrative embodiment, if the selected video content is restricted, it can be determined whether one or more types of credentials are received during the call. For example, at decision step 316, it can be determined whether caller identification information received at the set-top box device with the incoming call matches caller identification information designated as a credential to allow recording of restricted video content. In an illustrative embodiment, the IVR, or hardware or software communicating with the IVR, can compare the caller identification received with the incoming call to caller identification that the set-top box user has designated as a credential for recording restricted video content. If the caller identification information received with the incoming call matches the caller identification information that the user has designated as a credential for recording restricted video content, the method moves to block 324. If the caller identification information received with the call does not match caller identification information designated by the user as a credential, or if the user has not designated caller identification information as a credential, the method continues to decision step 318.

In a particular embodiment, the set-top box device can store one or more voice prints, which the user can designate as a credential for recording restricted video content. At decision step 318, it can be determined whether one or more voice commands received at the set-top box device with the incoming call matches a voice print designated as a credential. In an illustrative embodiment, the IVR, or hardware or software communicating with the IVR, can compare the voice command(s) received during the call to one or more voice prints that the set-top box user has designated as a credential for recording restricted video content. If the voice command(s) matches a voice print that the user has designated as a credential, the method moves to block 324. If the voice command(s) do not match a voice print designated by the user as a credential, or if the user has not designated a voice print as a credential, the method continues to block 320.

Moving to block 320, the IVR can prompt the caller for a control code, such as a PIN, password or passcode. The caller can speak the control code to the IVR or enter it, for example, using keys on the caller's phone. Proceeding to decision step 322, it can be determined whether the control code matches a control code designated as a credential. In an illustrative embodiment, the IVR, or hardware or software communicating with the IVR, can compare the control code communicated by the caller during the call to a control code that the set-top box user has designated as a credential for recording restricted video content. If the control code communicated to the IVR by the caller does not match the control code designated by the user as a credential, the method proceeds to block 330, and an error message indicating that the selected content is unavailable to be recorded can be communicated to the caller by the IVR. The method then moves to decision step 356 and continues as described. Conversely, if the control code communicated by the caller matches the control code designated by the user as a credential, the method proceeds to block 324.

Proceeding to block 324, if the selected video content is available and unrestricted, or if a matching credential has been communicated to the IVR by the caller, the IVR can prompt the caller for data related to the video content that is to be recorded, such as a movie channel, a television station call letter, a television station call number, a television channel number, a television program title, a user-defined television station identifier, a user-defined movie channel identifier, a movie time, a television program time, a movie date, a television program date, or a combination thereof. Continuing to block 326, a digital video recorder (DVR) within the set-top box device can be scheduled to record the selected video content, according to the related data received from the caller. In one embodiment, the IVR, or hardware or software communicating with the IVR, can transmit programming commands to the DVR to record the selected video content, as scheduled. Moving to block 332, the IVR can communicate a conformation that the DVR has been scheduled to record the selected video content. The method then proceeds to decision step 356 and continues as described.

Returning to decision step 306, if the caller communicates a selection to manage recorded video content that is stored at the set-top box device, the method moves to decision step 334. In a particular embodiment, at decision step 334, it can be determined whether the caller wishes to hear a list of the video content stored at a DVR or other video content storage module within the set-top box device. For instance, the caller can be prompted with a menu that contains selections of management functions that include communicating a video content list. If the caller communicates a voice or other input command to the IVR not to hear the video content list, the method moves to decision step 338. Conversely, if the caller communicates a voice or other input command to the IVR to hear the video content list, the method proceeds to block 336, and the IVR communicates the list to the caller. In one embodiment, the IVR, or hardware or software communicating with the IVR, can retrieve a list of recorded video content from the DVR or other video content storage module. The method then continues to decision step 338.

Moving to decision step 338, it can be determined whether the caller wishes to schedule playback of recorded video content. For instance, the caller can be prompted with a menu that includes a selection to schedule playback for particular video content. If the caller communicates a voice or other input command not to schedule playback of recorded video content, the method moves to decision step 342. On the other hand, if the caller communicates a voice or other input command to schedule playback of recorded video content, the method moves to block 340, and the IVR prompts the caller for a selection of recorded video content and a desired playback time. The method then proceeds to decision step 342, and the DVR is scheduled to playback the recorded video content at the scheduled time. The method then proceeds to decision step 344.

Proceeding to decision step 344, it can be determined whether the caller wishes to delete recorded video content from the DVR or other video content storage module. In a particular embodiment, the caller can be prompted with a menu that includes a selection to delete recorded video content. If the caller communicates a voice or other input command not to delete recorded video content, the method moves to decision step 350. Whereas, if the caller communicates a voice or other input command to delete recorded video content, the method moves to block 346, and the IVR prompts the caller for a selection of recorded video content to be deleted. The method then proceeds to decision step 348, and the IVR, or hardware or software communicating with the IVR, can issue a command to the DVR to delete the recorded video content indicated by the caller. The method then proceeds to decision step 350.

At decision step 350, it can be determined whether the caller wishes to set restrictions on video content that can be recorded at the set-top box device. The caller can be prompted, for example, with a menu that includes a selection to designate restricted video content. If the caller communicates a voice or other input command not to designate restricted video content, the method moves to decision step 356. On the other hand, if the caller communicates a voice or other input command to designate restricted video content, the method moves to block 352, and the IVR prompts the caller for a designation of restricted video content. Such designations can include video content names, video content audience ratings, television or movie channels, pay-per-view channels, or video-on-demand channels. The method then proceeds to decision step 354, and the IVR can prompt the caller for a credential, that can be used to allow recording of the restricted video content. The credential can include caller identification information; a voice print; a control code, such as a password or PIN; or any combination thereof. The method then proceeds to decision step 356.

Moving to decision step 356, the IVR can prompt the user to enter a new voice or other input command. In one embodiment, the IVR can ask the caller if he or she wishes to perform a new action, such as scheduling additional video content to be recorded or performing additional management functions. If the caller communicates a selection to enter a new voice or other input command, the method returns to decision step 306. If the caller communicates a selection not to enter a new voice or other input command, the method terminates at 358.

Though the aspects of the disclosed method have been presented in a certain order, for ease of description, certain portions of the method may be performed in a different order or simultaneously. For example, a caller can be prompted with selections for various management or recording functions in a single menu level, or at various levels of a multi-level menu.

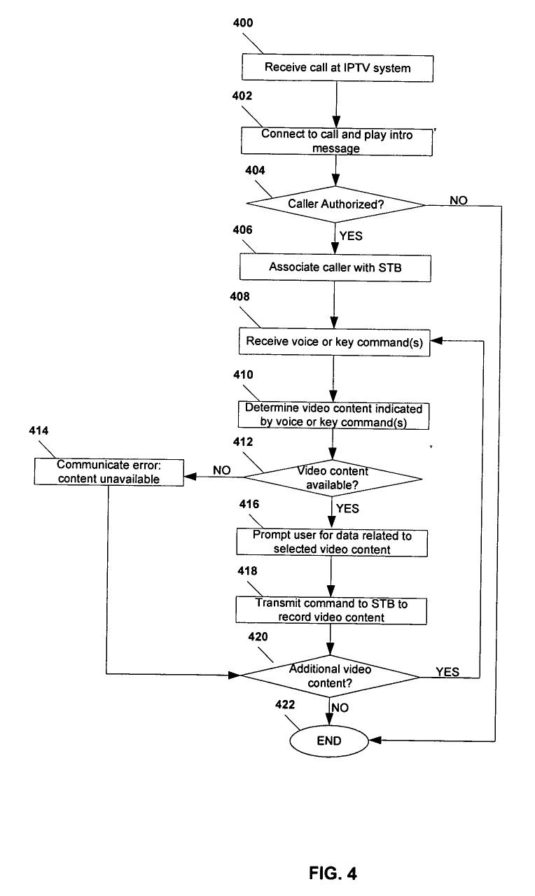

Referring to FIG. 4, a second embodiment of a method of recording video content is illustrated. At block 400, an incoming call is received at an Internet Protocol Television (IPTV) system. In a particular embodiment, the call can be routed over a public telephone network, such as a plain old telephone service (POTS) network or a Voice over Internet Protocol (VoIP) network, to a call center using an identifier associated with one or more communication servers within the IPTV system. Continuing to block 402, the communication server(s) are connected to the call. In a particular embodiment, an interactive voice response logic module (IVR) within the communication server(s) can answer the call and communicate an introductory message that informs the caller that the call has been answered.

Proceeding to block 404, it can be determined whether the caller is authorized to record video content via the IPTV system. In an illustrative embodiment, the IVR, or hardware or software communicating with the IVR, can receive caller identification information with the incoming call. The IVR or other hardware or software can include instructions or logic to query an information store that contains subscriber or user account information for the IPTV system. If the caller identification information received with the call is not associated with a user account stored by the information store, the method can terminate at 420. On the other hand, if the caller identification information received with the call is associated with a user account stored by the information store, the method can proceed to block 406. In another embodiment, the caller can speak a name, or speak or enter a PIN or password. The name, PIN or password can be compared with subscriber or user accounts stored at the information store, in order to determine whether the caller is authorized to record video content. In one embodiment, the caller can speak the name, PIN or password, and the caller's voice can be compared to one or more voice prints stored with the account corresponding to the name, PIN or password.

Moving to block 406, the caller is associated with a set-top box device. In one embodiment, subscriber or user account information retrieved at decision step 404 can be used to associate an identifier of a set-top box with the caller. Set-top box identifiers can include, for example, an alphanumeric identifier of a set-top box device, a phone number, an address of a set-top box device, an identity of a twisted pair or fiber optic cable coupled to a set-top box device, an Internet Protocol (IP) address of a set-top box device, or any combination thereof.

During the call, the IVR can receive one or more voice commands that identify video content to be recorded at the set-top box device. For instance, the caller can speak a voice command corresponding to one of the menu selections, such as ‘record Monday Night Football.’ Alternatively, the caller can input one or more letters included in the video content name using telephone keys, such as keys that generate dual tone multi frequency (DTMF) signals, and the caller could then use voice commands to select from video content choices having those letters. In an illustrative embodiment, the IVR can present the caller with a main menu that includes selectable options to record video content at the set-top box device associated with the caller. For instance, a first menu level can prompt the user for a date on which the video content to be recorded will be aired or shown; a second menu level can prompt the caller for a channel or station on which the video content to be recorded will be aired or shown; a third menu level can prompt the user for a time at which the video content to be recorded will be aired or shown. The caller can navigate through the menu by using voice commands that identify dates, channels, times, and programs, or by using voice or other input commands, such as ‘one,’ ‘two,’ and so on, which correspond to menu selections.

Moving to block 410, the IVR, or hardware or software communicating with the IVR, determines the video content indicated by the voice or other input command(s) received at block 408. The method then moves to decision step 412, and it is determined whether the video content selected by the caller is available for recording. In an illustrative embodiment, the IVR, or other hardware or software communicating with the IVR, can query one or more servers within the IPTV system for availability of the video content selected by the caller. If the selected video content is not available to be recorded, the method can proceed to block 414, and an error message indicating that the selected video content is unavailable can be communicated by the IVR to the caller. The method then continues to decision step 420. On the other hand, if the selected video content is available, the method moves to block 416.

Proceeding to block 416, if the selected video content is available, the IVR can prompt the caller for data related to the video content that is to be recorded, such as a movie channel, a television station call letter, a television station call number, a television channel number, a television program title, a user-defined television station identifier, a user-defined movie channel identifier, a movie time, a television program time, a movie date, a television program date, or a combination thereof. Continuing to block 418, the communication server, or a device coupled thereto, can issue a command to the set-top box device associated with the caller, or to a DVR or other video content storage module therein, to record the selected video content, according to the time, station, and other data received from the caller. In one embodiment, the IVR, or hardware or software communicating with the IVR, can transmit programming commands or signals to the DVR over an external access network, such as a private access network within the IPTV system to record the selected video content, as scheduled. The method continues to decision step 420.

At decision step 420, the IVR can prompt the caller for a selection to schedule any additional video content selections to be recorded. If the caller selects to schedule additional video content for recording, the method returns to block 408. Whereas, if the caller selects not to schedule additional video content for recording, the method terminates at 422.

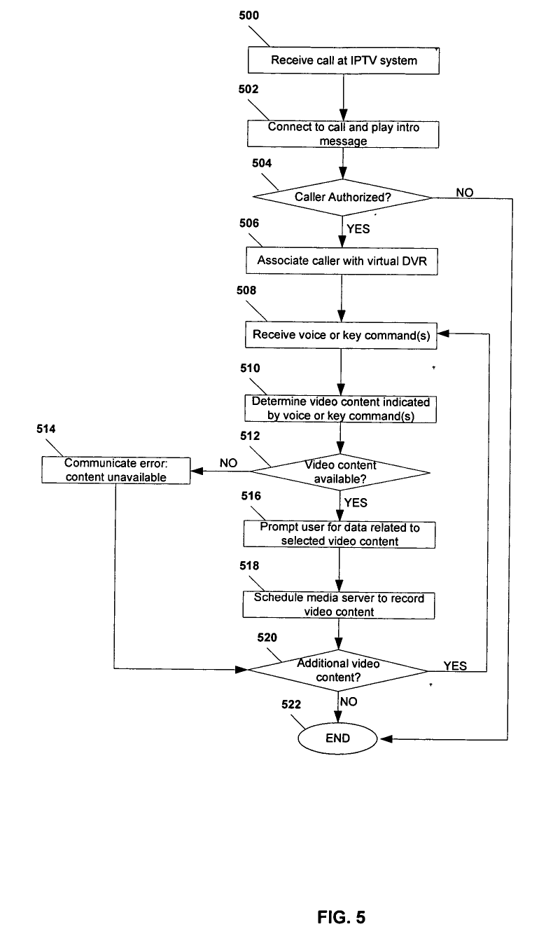

Referring to FIG. 5, another embodiment of a method of recording video content is illustrated. At block 500, an incoming call is received at an Internet Protocol Television (IPTV) system. In a particular embodiment, the call can be routed over a public telephone network, such as a plain old telephone service (POTS) network, to a call center using an identifier associated with one or more communication servers within the IPTV system. Continuing to block 502, the communication server(s) connect to the call. In a particular embodiment, an interactive voice response logic module (IVR) within the communication server(s) can answer the call and communicate an introductory message that informs the caller that the call has been answered.

Proceeding to block 504, it can be determined whether the caller is authorized to record video content via the IPTV system. In an illustrative embodiment, the IVR, or hardware or software communicating with the IVR, can receive caller identification information with the incoming call. The IVR or other hardware or software can include instructions or logic to query an information store that contains subscriber or user account information for the IPTV system. If the caller identification information received with the call is not associated with a user account stored by the information store, the method can terminate at 520. On the other hand, if the caller identification information received with the call is associated with a user account stored by the information store, the method can proceed to block 506. In another embodiment, the caller can speak a name, or speak or enter a PIN or password. The name, PIN or password can be compared with subscriber or user accounts stored at the information store, in order to determine whether the caller is authorized to record video content via the IPTV system. In one embodiment, the caller can speak the name, PIN or password, and the caller's voice can be compared to one or more voice prints stored with the account corresponding to the name, PIN or password.

In an illustrative embodiment, at block 506, the caller can be associated with a virtual digital video recorder (DVR) at a recorded media server within the IPTV system. For instance, the recorded media server can include one or more DVRs, each of which can be logically partitioned into a plurality of virtual DVRs. In one embodiment, subscriber or user account information retrieved at decision step 504 can associate an identifier of a virtual DVR with the caller. In another embodiment, a plurality of voice prints can be associated with the user account corresponding to the caller. The caller can speak a name, PIN or password, and the caller's voice can be compared to the voice prints. If the caller's voice matches a first voice print, the caller can be associated with a first virtual DVR at the recorded media server. If the caller's voice matches another voice print, the caller can be associated with another virtual DVR at the recorded media server.

During the call, the IVR can receive one or more voice commands that identify video content to be recorded at the set-top box device. For instance, the caller can speak a voice command corresponding to one of the menu selections, such as ‘record Monday Night Football.’ Alternatively, the caller can input one or more letters included in the video content name using telephone keys, such as keys that generate dual tone multi frequency (DTMF) signals, and the caller could then use voice commands to select from video content choices having those letters. In an illustrative embodiment, the IVR can present the caller with a main menu that includes selectable options to record video content at the set-top box device associated with the caller. For instance, a first menu level can prompt the user for a date on which the video content to be recorded will be aired or shown; a second menu level can prompt the caller for a channel or station on which the video content to be recorded will be aired or shown; a third menu level can prompt the user for a time at which the video content to be recorded will be aired or shown. The caller can navigate through the menu by using voice commands that identify dates, channels, times, and programs, or by using voice or other input commands, such as ‘one,’ ‘two,’ and so on, which correspond to menu selections.

Moving to block 510, the IVR, or hardware or software communicating with the IVR, determines the video content indicated by the voice or other input command(s) received at block 508. The method then moves to decision step 512, and it is determined whether the video content selected by the caller is available for recording. In an illustrative embodiment, the IVR, or other hardware or software communicating with the IVR, can query one or more servers within an IPTV system for availability of the video content selected by the caller. If the selected video content is not available to be recorded, the method can proceed to block 514, and an error message indicating that the selected video content is unavailable can be communicated by the IVR to the caller. The method then continues to decision step 520. On the other hand, if the selected video content is available, the method moves to block 516.

Proceeding to block 516, if the selected video content is available, the IVR can prompt the caller for data related to the video content that is to be recorded, such as a movie channel, a television station call letter, a television station call number, a television channel number, a television program title, a user-defined television station identifier, a user-defined movie channel identifier, a movie time, a television program time, a movie date, a television program date, or a combination thereof. Continuing to block 518, the communication server, or a device coupled thereto, can issue a command to a recorded media server within the IPTV system to record the selected video content, according to the time, station, and other data received from the caller. In a particular embodiment, the IVR, or hardware or software communicating with the IVR, can transmit programming commands or signals to the virtual DVR with which the caller is associated, over a private network within the IPTV system. The method continues to decision step 520.

At decision step 520, the IVR can prompt the caller for a selection to schedule any additional video content selections to be recorded. If the caller selects to schedule additional video content for recording, the method returns to block 508. Whereas, if the caller selects not to schedule additional video content for recording, the method terminates at 522.

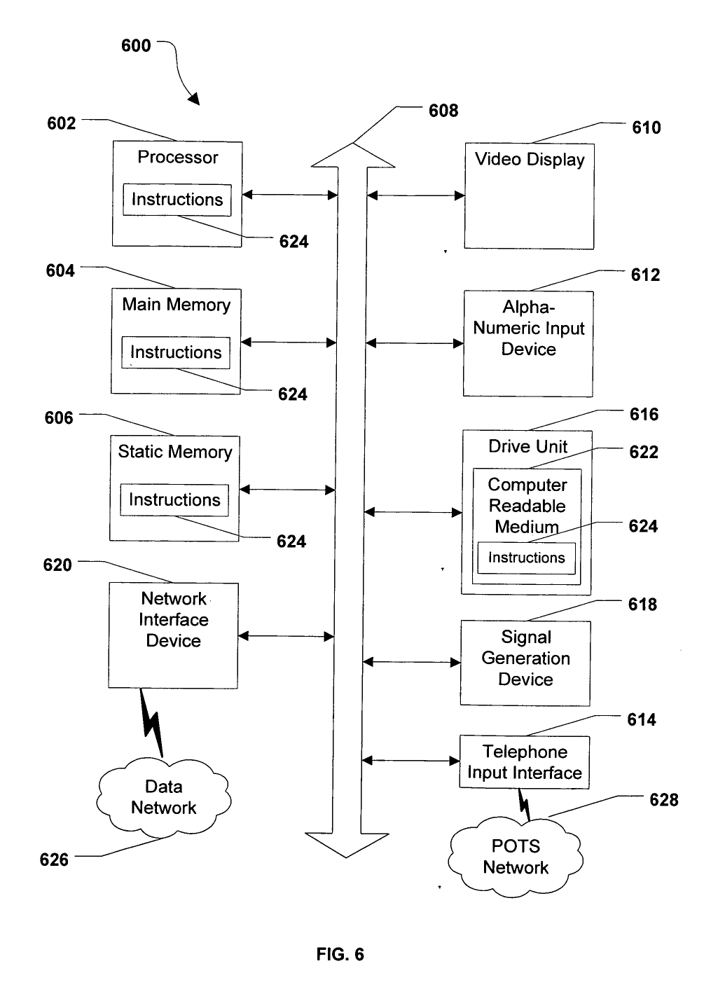

Referring to FIG. 6, an illustrative embodiment of a general computer system is shown and is designated 600. The computer system 600 can include a set of instructions that can be executed to cause the computer system 600, or a portion thereof, to perform any one or more of the methods or computer based functions disclosed herein in connection with the set-top box device or with a network device. The computer system 600, or any portion thereof, may operate as a standalone device or may be a hardware or software module within a server or set-top box device, as illustrated in FIGS. 1 and 2.

In a networked deployment, the computer system may operate in the capacity of an IPTV server or set-top box device. The computer system 600 can also be implemented as or incorporated into various other devices, or any other machine capable of executing a set of instructions (sequential or otherwise) that specify actions to be taken by that machine. In a particular embodiment, the computer system 600 can be implemented using electronic devices that provide audio, video or data communication. Further, while a single computer system 600 is illustrated, the term “system” shall also be taken to include any collection of systems or sub-systems that individually or jointly execute a set, or multiple sets, of instructions to perform one or more computer functions, such as the IPTV system illustrated in FIG. 1.

As illustrated in FIG. 6, the computer system 600 may include a processor 602, e.g., a central processing unit (CPU), a graphics-processing unit (GPU), or both. Moreover, the computer system 600 can include a main memory 604 and a static memory 606 that can communicate with each other via a bus 608. As shown, the computer system 600 may further include a video display unit 610, such as a liquid crystal display (LCD), an organic light emitting diode (OLED), a flat panel display, a solid state display, or a cathode ray tube (CRT). Additionally, the computer system 600 may include an input device 612, such as an input control panel, and a telephone input interface 614. In a particular embodiment, the telephone input interface 614 can be coupled to a plain old telephone service (POTS) or other public telephone network. The computer system 600 can also include a disk drive unit 616, a signal generation device 618, such as a speaker or remote control, and a network interface device 620.

In a particular embodiment, as depicted in FIG. 6, the disk drive unit 616 may include a computer-readable medium 622 in which one or more sets of instructions 624, e.g. software, can be embedded. Further, the instructions 624 may embody one or more of the methods or logic as described herein. In a particular embodiment, the instructions 624 may reside completely, or at least partially, within the main memory 604, the static memory 606, and/or within the processor 602 during execution by the computer system 600. The main memory 604 and the processor 602 also may include computer-readable media.

In an alternative embodiment, dedicated hardware implementations, such as application specific integrated circuits, programmable logic arrays and other hardware devices, can be constructed to implement one or more of the methods described herein. Applications that may include the apparatus and systems of various embodiments can broadly include a variety of electronic and computer systems. One or more embodiments described herein may implement functions using two or more specific interconnected hardware modules or devices with related control and data signals that can be communicated between and through the modules, or as portions of an application-specific integrated circuit. Accordingly, the present system encompasses software, firmware, and hardware implementations.

In accordance with various embodiments of the present disclosure, the methods described herein may be implemented by software programs executable by a computer system. Further, in an exemplary, non-limited embodiment, implementations can include distributed processing, component/object distributed processing, and parallel processing. Alternatively, virtual computer system processing can be constructed to implement one or more of the methods or functionality as described herein.

The present disclosure contemplates a computer-readable medium that includes instructions 624 or receives and executes instructions 624 responsive to a propagated signal, so that a device connected to a network 626 can communicate audio, video or data over the network 626. Further, the instructions 624 may be transmitted or received over the network 626 via the network interface device 620.

While the computer-readable medium is shown to be a single medium, the term “computer-readable medium” includes a single medium or multiple media, such as a centralized or distributed database, and/or associated caches and servers that store one or more sets of instructions. The term “computer-readable medium” shall also include any medium that is capable of storing, encoding or carrying a set of instructions for execution by a processor or that cause a computer system to perform any one or more of the methods or operations disclosed herein.

In a particular non-limiting, exemplary embodiment, the computer-readable medium can include a solid-state memory such as a memory card or other package that houses one or more non-volatile read-only memories. Further, the computer-readable medium can be a random access memory or other volatile re-writable memory. Additionally, the computer-readable medium can include a magneto-optical or optical medium, such as a disk or tapes or other storage device to capture carrier wave signals such as a signal communicated over a transmission medium. A digital file attachment to an e-mail or other self-contained information archive or set of archives may be considered a distribution medium that is equivalent to a tangible storage medium. Accordingly, the disclosure is considered to include any one or more of a computer-readable medium or a distribution medium and other equivalents and successor media, in which data or instructions may be stored.

In a particular embodiment, the steps of the methods described herein are executed in the order shown by the figures. In alternative embodiments, the steps may be executed in alternative sequences.

In conjunction with the configuration of structure described herein, the system and method disclosed enable set-top box users to schedule selected video content to be recorded at a set-top box device or network device, via a remote telephone. In one embodiment, an interactive voice response module can receive voice or other input commands from a caller and cause programming commands corresponding to the selected video content to be issued to a DVR within a set-top box device associated with the caller. The set-top box can receive the selected video content via an external access network, such as a private access network of an IPTV system, and the selected video content can be recorded by the DVR. In another embodiment, programming commands can be issued from a communication server within an IPTV system to a virtual DVR at a network server within the IPTV system to record selected video content and to download the selected video content to an associated set-top box device, when a request for the selected video content is received at the IPTV system from the set-top box device. In yet another embodiment, programming commands can be issued from a communication server within an IPTV system to a set-top box device over a private access network within the IPTV system to record the selected video content.

Although the present specification describes components and functions that may be implemented in particular embodiments with reference to particular standards and protocols, the invention is not limited to such standards and protocols. For example, standards for Internet and other packet switched network transmission (e.g., TCP/IP, UDP/IP, HTML, HTTP) represent examples of the state of the art. Such standards are periodically superseded by faster or more efficient equivalents having essentially the same functions. Accordingly, replacement standards and protocols having the same or similar functions as those disclosed herein are considered equivalents thereof.

The illustrations of the embodiments described herein are intended to provide a general understanding of the structure of the various embodiments. The illustrations are not intended to serve as a complete description of all of the elements and features of apparatus and systems that utilize the structures or methods described herein. Many other embodiments may be apparent to those of skill in the art upon reviewing the disclosure. Other embodiments may be utilized and derived from the disclosure, such that structural and logical substitutions and changes may be made without departing from the scope of the disclosure. Additionally, the illustrations are merely representational and may not be drawn to scale. Certain proportions within the illustrations may be exaggerated, while other proportions may be minimized. Accordingly, the disclosure and the figures are to be regarded as illustrative rather than restrictive.

One or more embodiments of the disclosure may be referred to herein, individually and/or collectively, by the term “invention” merely for convenience and without intending to voluntarily limit the scope of this application to any particular invention or inventive concept. Moreover, although specific embodiments have been illustrated and described herein, it should be appreciated that any subsequent arrangement designed to achieve the same or similar purpose may be substituted for the specific embodiments shown. This disclosure is intended to cover any and all subsequent adaptations or variations of various embodiments. Combinations of the above embodiments, and other embodiments not specifically described herein, will be apparent to those of skill in the art upon reviewing the description.

The Abstract of the Disclosure is provided to comply with 37 C.F.R. § 1.72(b) and is submitted with the understanding that it will not be used to interpret or limit the scope or meaning of the claims. In addition, in the foregoing Detailed Description, various features may be grouped together or described in a single embodiment for the purpose of streamlining the disclosure. This disclosure is not to be interpreted as reflecting an intention that the claimed embodiments require more features than are expressly recited in each claim. Rather, as the following claims reflect, inventive subject matter may be directed to less than all of the features of any of the disclosed embodiments. Thus, the following claims are incorporated into the Detailed Description, with each claim standing on its own as defining separately claimed subject matter.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A method of recording video content, the method comprising:
receiving a call at a set-top box device, the call routed using an identifier associated with the set-top box device;
receiving a voice command at the set-top box device, wherein the voice command identifies selected video content to be recorded;
receiving the selected video content via an external access network coupled to the set-top box device; and
recording the selected video content at the set-top box device.

2. The method of claim 1, wherein the identifier is a telephone number.

3. The method of claim 1, further comprising prompting a caller for a video-on-demand program title, a movie program title, a movie channel, a television station call letter, a television station call number, a television channel number, a television program title, a user-defined television station identifier, a user-defined movie channel identifier, a movie time, a television program time, a movie date, a television program date, or a combination thereof.

4. The method of claim 1, wherein the selected video content includes movie content, video-on-demand content, broadcast television content, or a combination thereof.

5. The method of claim 1, further comprising:
submitting a request from the set-top box device to a video content server via the external access network; and
receiving the selected video content at the set-top box device, via the external access network, in response to the request.

6. The method of claim 1, further comprising determining whether the selected video content is stored at the set-top box prior to recording the selected video content.

7. The method of claim 1, further comprising:
receiving a selection to view the selected video content; and
transmitting the selected video content to a display device coupled to the set-top box device.

8. The method of claim 1, wherein the voice command includes a playback time and the set-top box device transmits recorded video content to a display device at the playback time.

9. The method of claim 1, wherein the voice command includes a delete command and the set-top box device deletes recorded video content from video content storage within the set-top box device.

10. The method of claim 1, wherein the voice command includes a designation of restricted video content and a credential.

11. The method of claim 10, further comprising:
recording the restricted video content when a matching credential is received; and
blocking recording of the restricted video content when a matching credential is not received.

12. The method of claim 11, further comprising:
transmitting the restricted video content to a display device when a matching credential is received; and
blocking transmission of the restricted video content to a display device when a matching credential is not received.

13. The method of claim 11, wherein the credential includes a voice print.

14. The method of claim 11, wherein the credential includes caller identification information.

15. A method of recording video content, the method comprising:
routing a call over a telephone network to a remote set-top box device using an identifier associated with the set-top box device; and
communicating a voice command to the set-top box device during the call, wherein the voice command identifies selected video content to be recorded at the remote set-top box device.

16. The set-top box device of claim 15, wherein the telephone network is a plain old telephone service (POTS) network.

17. A set-top box device, comprising:
a telephone network interface configured to receive a call routed using an identifier associated with the set-top box device;
a voice command logic module configured to receive a voice command via the telephone network interface, wherein the voice command identifies selected video content to be recorded; and
a video content storage module responsive to the voice command logic module to record the selected video content.

18. The set-top box of claim 17, wherein the voice command logic module includes an interactive voice response system.

19. The set-top box device of claim 17, further comprising a media control logic module configured to receive the selected video content via an external access network and to transmit the selected video content to a video content storage module.

20. The set-top box device of claim 19, wherein the external access network is a private network within an Internet Protocol Television (IPTV) system.

21. The set-top box device of claim 17, wherein the video content storage module includes a digital video recorder.

22. The set-top box device of claim 17, wherein the voice command logic module includes interactive voice response logic to prompt the caller for a video program title, a video content channel, a television station call letter, a television station call number, a television channel number, a television program title, a user-defined television station identifier, a user-defined video content channel identifier, a video program time, a television program time, a video program date, a television program date, or a combination thereof.

23. The set-top box device of claim 17, further comprising a memory device within the set-top box device that is configured to store at least one first voice print associated with a first user and a designation of restricted video content associated with the first user.

24. The set-top box device of claim 23, wherein:
the media control logic module includes logic to compare the voice command with the first voice print;
the media control logic module includes logic to schedule recording of the restricted video content when the voice command matches the first voice print; and
the media control logic module includes logic to block recording of the restricted video content when the voice command does not match the first voice print.

25. A method of recording video content, the method comprising:
receiving a call at a server of an Internet Protocol Television (IPTV) system, the call routed using an identifier associated with the server;
associating the call with a set-top box device;
receiving a voice command at the server, wherein the voice command identifies selected video content to be recorded; and
issuing a programming command to a device via the IPTV system to record the selected video content.

26. The method of claim 25, wherein the device is the set-top box device.

27. The method of claim 25, wherein the device is a recorded media server.

28. The method of claim 27, wherein the video content is downloaded from the recorded media server to the set-top box device.

29. The method of claim 25, wherein the device includes a digital video recorder.

30. The method of claim 25, wherein the server associates the call with the set-top box device based at least partially on a voice print match, caller identification information, a password, a personal identification number, or a combination thereof.

31. The method of claim 25, further comprising storing at least one first voice print associated with a first user and at least one second voice print associated with a second user.

32. The method of claim 31, further comprising:
comparing the voice command with the first voice print;
scheduling recording of the selected video content at a first virtual digital video recorder when the voice command matches the first voice print; and
scheduling recording of the selected video content at a second virtual digital video recorder when the voice command matches the second voice print.

33. A computer program embedded in a computer-readable medium, the computer program comprising:
instructions to process a received voice command communicated during a call to a set-top box device, the call routed using an identifier associated with the set-top box device, wherein the voice command identifies selected video content to be recorded; and
instructions to schedule recording of the selected video content at a video content storage module of the set-top box device.

34. The computer program of claim 33, wherein the instructions to schedule recording of the selected video content are transmitted to the video content storage module via a media control logic module.

35. The computer program of claim 33, wherein the video content storage module is a digital video recorder that records the selected video content when scheduled.
